(19) United States
(12) Patent Application Publication
(10) Pub. No.: US 2025/0008658 A1
(43) Pub. Date: Jan. 2, 2025

(54) DISPLAY DEVICE INCLUDING A FLEXIBLE CIRCUIT BOARD

(71) Applicant: SAMSUNG DISPLAY CO., LTD., YONGIN-SI (KR)

(72) Inventor: KIHAE SHIN, Yongin-si (KR)

(21) Appl. No.: 18/680,235

(22) Filed: May 31, 2024

(30) Foreign Application Priority Data
Jun. 27, 2023 (KR) 10-2023-0082443

(51) Int. Cl. H05K 1/14; H05K 5/03

(52) U.S. Cl. CPC H05K 1/147; H05K 5/03; H05K 2201/10128

(57) ABSTRACT

A display device including: a display panel; a plurality of flexible circuit boards connected to the display panel and are bent and disposed under the display panel; a main circuit board connected to the flexible circuit boards and disposed under the display panel; a first cover disposed on the display panel. The first cover is bent with a curvature and disposed on a rear surface of the display panel, covering portions of the flexible circuit boards and the main circuit board; and a second cover covering parts of the flexible circuit boards.

### CROSS-REFERENCE TO RELATED APPLICATIONS

This application claims priority under 35 U.S.C. § 119 to Korean Patent Application No. 10-2023-0082443, filed on Jun. 27, 2023, in the Korean Intellectual Property Office, the disclosures of which are incorporated by reference herein in their entireties.

### TECHNICAL FIELD

Embodiments of the present disclosure described herein relate to a display device and more specifically, to a display device including a flexible circuit board.

### DISCUSSION OF THE RELATED ART

Display devices such as televisions, monitors, smart phones, and tablet personal computers (PCs) that provide images to users include display panels that display images. The display panels come in various types such as liquid crystal display panels, organic light emitting display panels, electro wetting display panels, and electrophoretic display panels.

The display device may include a flexible circuit board connected to the display panel and a main circuit board connected to the display panel through the flexible circuit board.

### SUMMARY

According to an embodiment, a display device includes a display panel; a plurality of flexible circuit boards connected to the display panel and are bent and disposed under the display panel; a main circuit board connected to the flexible circuit boards and disposed under the display panel; a first cover disposed on the display panel. The first cover is bent with a curvature and disposed on a rear surface of the display panel, covering portions of the flexible circuit boards and the main circuit board; and a second cover covering parts of the flexible circuit boards which exposed from the first cover.

According to an embodiment, a display device includes a display panel; a first flexible circuit board connected to and bent from a center of an edge of the display panel; a second flexible circuit board connected to and bent from the edge of the display panel, spaced apart from the first flexible circuit board, and adjacent to one side of the edge of the display panel; a main circuit board disposed on a lower surface of the display panel and connected to the first flexible circuit board and the second flexible circuit board; a first cover covering the first flexible circuit board and the main circuit board; and a second cover covering the second flexible circuit board.

### BRIEF DESCRIPTION OF THE FIGURES

The above and other objects and features of the present disclosure will become apparent by describing in detail embodiments thereof with reference to the accompanying drawings.

FIG. 1 is a perspective view of a display device according to an embodiment of the present disclosure.

FIG. 2 is a cross-sectional view of a display module included in the display device of FIG. 1.

FIG. 3 is a cross-sectional view of a display panel illustrated in FIG. 2.

FIGS. 4A, 4B and 4C are plan views of the display panel illustrated in FIG. 3.

FIG. 5 is a view exemplarily illustrating a cross section of a display module corresponding to any one pixel illustrated in FIG. 4A.

FIGS. 6A, 6B, 6C, 6D, 6E, 6F and 6G are views for describing a first cover.

FIGS. 7A, 7B, 7C, 7D and 7E are views for describing second cover.

FIG. 8A is a view for describing a structure of the first cover.

FIG. 8B is a view for describing the first cover grounded to a main circuit board.

FIG. 8C is a view for describing the first cover grounded to a cover panel.

FIGS. 9A, 9B, 9C and 9D are views for describing a first cover according to an embodiment of the present disclosure.

### DETAILED DESCRIPTION

Advantages and features of the present disclosure and a method of achieving the advantages and the features will become apparent with reference to an embodiment described below in detail in conjunction with the accompanying drawings. However, the present disclosure is not necessarily limited to the embodiments described below but will be implemented in various forms, and the present embodiments merely make the disclosure of the present disclosure complete, are provided to completely inform the scope of the present disclosure to those skilled in the art to which the present disclosure belongs, and are merely defined by the scope of the appended claims. Throughout the specification, the same reference numerals refer to the same components.

When it is mentioned that a first element or layer is disposed “on” or “above” a second element or layer, this includes both a case in which the first element or layer is directly on or above the second element or layer and a case in which a third element or layer is interposed therebetween. On other hand, when it is mentioned that the first element is disposed directly “on” or “above” the second element, this indicates that the third element or layer is not interposed therebetween. The term “and/or” includes each of mentioned items and all combinations of one or more of the mentioned items.

Spatially relative terms such as “below”, “beneath”, “lower”, “above”, and “upper” may be used to easily describe a correlation between a first element or component and a second element or component as illustrated in the drawings. The spatially relative terms should be understood as terms including different directions of elements during use or operation in addition to directions illustrated in the drawings. Throughout the specification, the same reference numerals may refer to the same components throughout the specification and the figures.

Although first, second, and the like are used to describe various elements, various components, and/or various sections, it is apparent that these elements, these components and/or these sections are not necessarily limited by these terms. These terms are used to distinguish one element, one component, or one section from another element, another component, or another section. Thus, it is apparent that a first element, a first component, or a first section mentioned below may be a second element, a second component, or a second section within the technical spirit of the present disclosure.

Embodiments described herein will be described with reference to a plan view and a cross-sectional view that are ideal schematic views of the present disclosure. Thus, a shape of an illustrative drawing may be modified due to a manufacturing technology and/or a tolerance. Thus, while each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

Hereinafter, an embodiment of the present disclosure will be described in more detail with reference to the accompanying drawings.

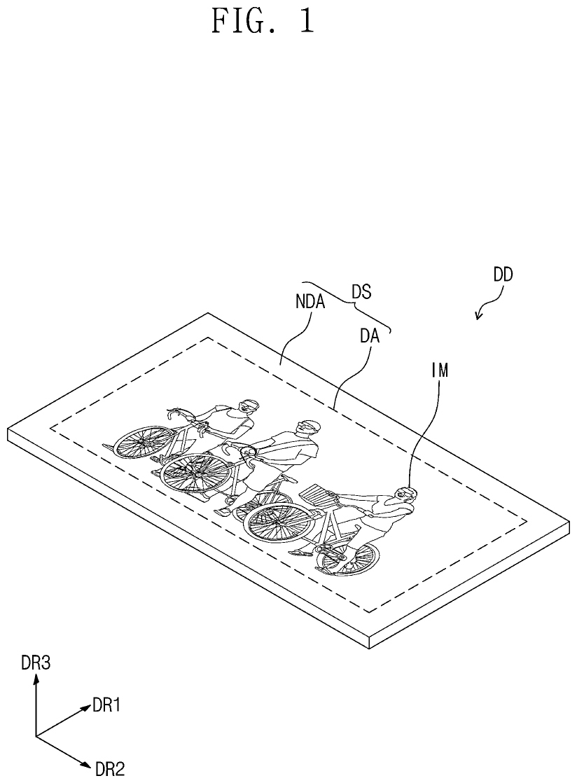

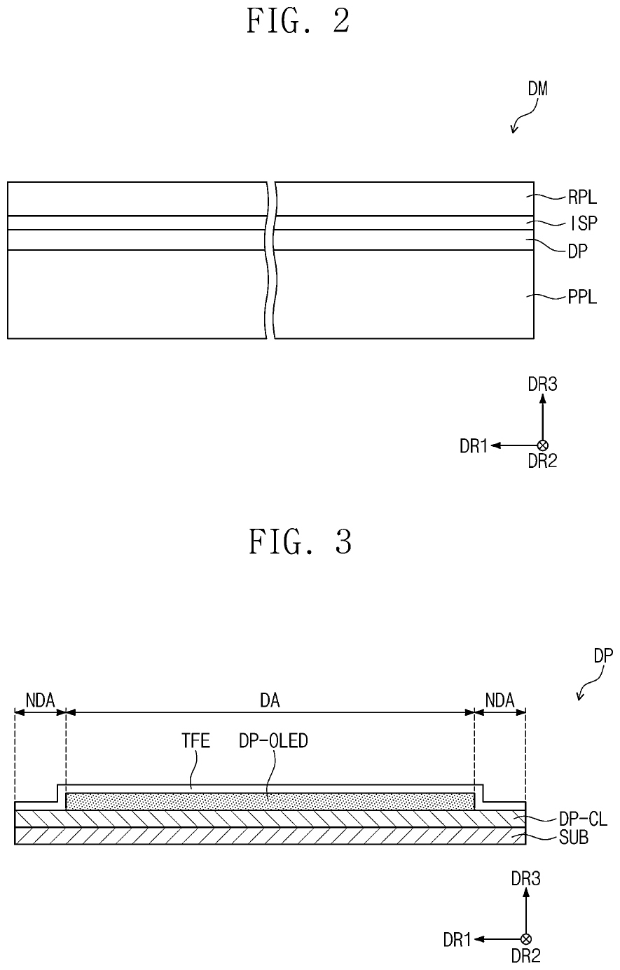

FIG. 1 is a perspective view of a display device according to an embodiment of the present disclosure. FIG. 2 is a cross-sectional view of a display module included in the display device of FIG. 1. FIG. 3 is a cross-sectional view of a display panel illustrated in FIG. 2.

Referring to FIG. 1, a display device DD according to an embodiment of the present disclosure may have a rectangular shape having shorter sides extending in a first direction DR1 and longer sides extending in a second direction DR2 intersecting the first direction DR1. However, the present disclosure is not necessarily limited thereto, and the display device DD may be various shapes such as a circular shape and polygonal shapes.

Hereinafter, a third direction DR3 is defined as being substantially perpendicular to a plane formed by the first direction DR1 and the second direction DR2. Further, in the present specification, the wording “when viewed on a plane” or “in a plan view” may be a state viewed from the third direction DR3.

An upper surface of the display device DD may be defined as a display surface DS. The display surface DS may have the plane defined by the first direction DR1 and the second direction DR2. Images IM generated by the display device DD may be provided to a user through the display surface DS.

The display surface DS may include a display area DA and a non-display area NDA proximate to the display area DA. The display area DA displays an image, and the non-display area NDA does not display the image. The non-display area NDA may at least partially surround the display area DA and define an edge of the display device DD, which is printed in a predetermined color.

Referring to FIG. 2, The display device DD may include a display module DM. The display module DM may include a display panel DP, an input sensing unit ISP disposed on the display panel DP, a reflection preventing layer RPL disposed on the input sensing unit ISP, and a panel protecting layer PPL disposed under the display panel DP. The display panel DP may be a flexible panel. For example, the display panel DP may include a flexible substrate and a plurality of elements arranged on the flexible substrate.

The display panel DP according to an embodiment of the present disclosure may be a light emitting display panel, but the present disclosure is not necessarily particularly limited thereto. For example, the display panel DP may be an organic light emitting display panel or an inorganic light emitting display panel. A light emitting layer of the organic light emitting display panel may include an organic light emitting material. A light emitting layer of the inorganic light emitting display panel may include a quantum dot, a quantum rod, or the like. Hereinafter, the display panel DP will be described as the organic light emitting display panel.

The input sensing unit ISP may include a plurality of sensor parts for detecting an external input in a capacitive manner. The input sensing unit ISP may be directly formed on the display panel DP when the display module DM is manufactured.

The reflection preventing layer RPL may be disposed on the input sensing unit ISP. The reflection preventing layer RPL may be directly formed on the input sensing unit ISP when the display module DM is manufactured. The reflection preventing layer RPL may be an external light reflection prevention film. The reflection preventing layer RPL may reduce a reflectance of an external light input from an upper side of the display device DD toward the display panel DP. The input sensing unit ISP may be directly formed on the display panel DP, and the reflection preventing layer RPL may be directly formed on the input sensing unit ISP, but an embodiment of the present disclosure is not necessarily limited thereto. For example, the input sensing unit ISP may be separately manufactured and attached to the display panel DP by an adhesive layer, and the reflection preventing layer RPL may be separately manufactured and attached to the input sensing unit ISP by an adhesive layer. Thus, the adhesive layer may be disposed between the input sensing unit ISP and the display panel DP, and also between the reflection preventing layer RPL and the input sensing unit ISP.

The panel protecting layer PPL may be disposed under the display panel DP and protect a lower portion of the display panel DP. The panel protecting layer PPL may include a flexible plastic material such as polyethylene terephthalate (PET).

Referring to FIG. 3, the display panel DP may include a substrate SUB, a circuit element layer DP-CL disposed on the substrate SUB, a display element layer DP-OLED disposed on the circuit element layer DP-CL, and a thin film encapsulation layer TFE disposed on the display element layer DP-OLED.

The substrate SUB may include the display area DA and the non-display area NDA proximate to the display area DA. For example, the display area DA may be disposed between the non-display area NDA. The display element layer DP-OLED may be disposed on the display area DA. The substrate SUB may include a flexible plastic material such as glass or polyimide (PI).

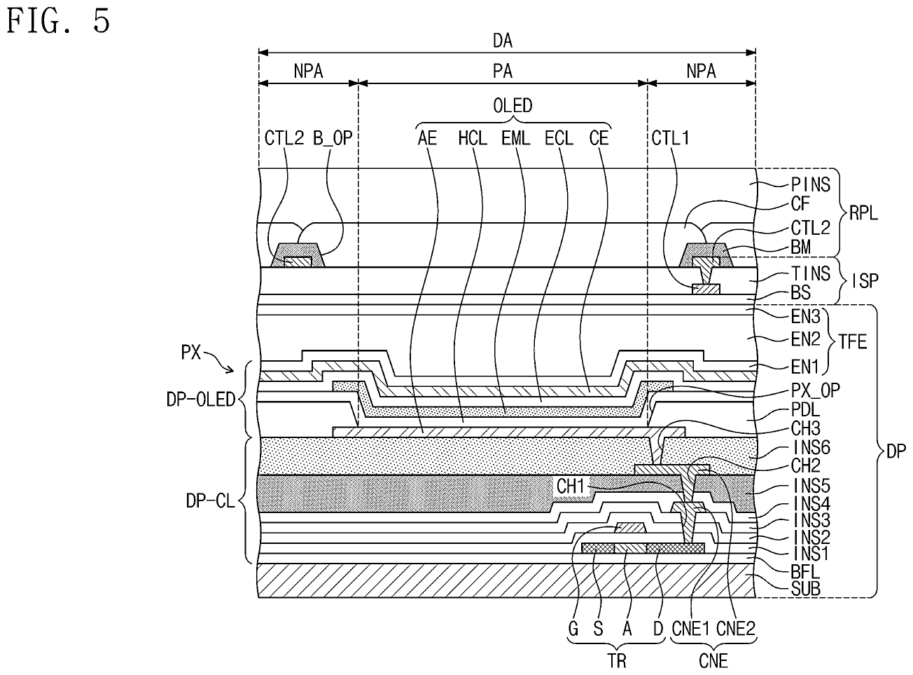

A plurality of pixels may be arranged in the circuit element layer DP-CL or the display element layer DP-OLED. Each of the pixels may include a transistor disposed on the circuit element layer DP-CL and a light emitting element disposed on the display element layer DP-OLED, connected to the transistor TR. A configuration of the pixel PX will be described in detail in FIG. 5.

The thin film encapsulation layer TFE may be disposed on the circuit element layer DP-CL, covering the display element layer DP-OLED. The thin film encapsulation layer TFE may protect the pixels PX from moisture, oxygen, and foreign substances.

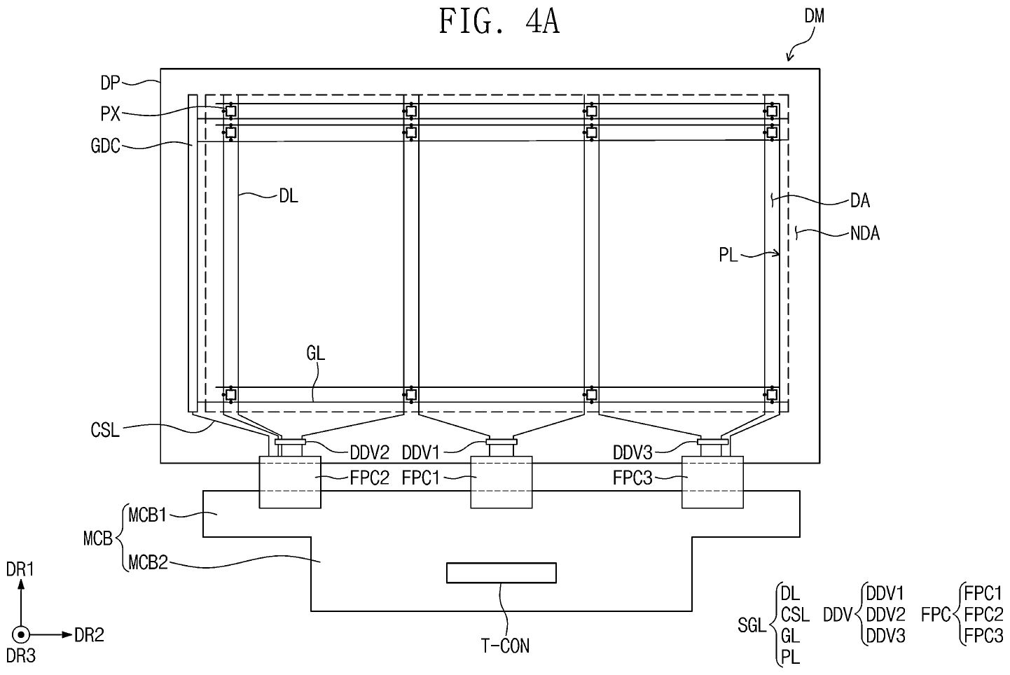

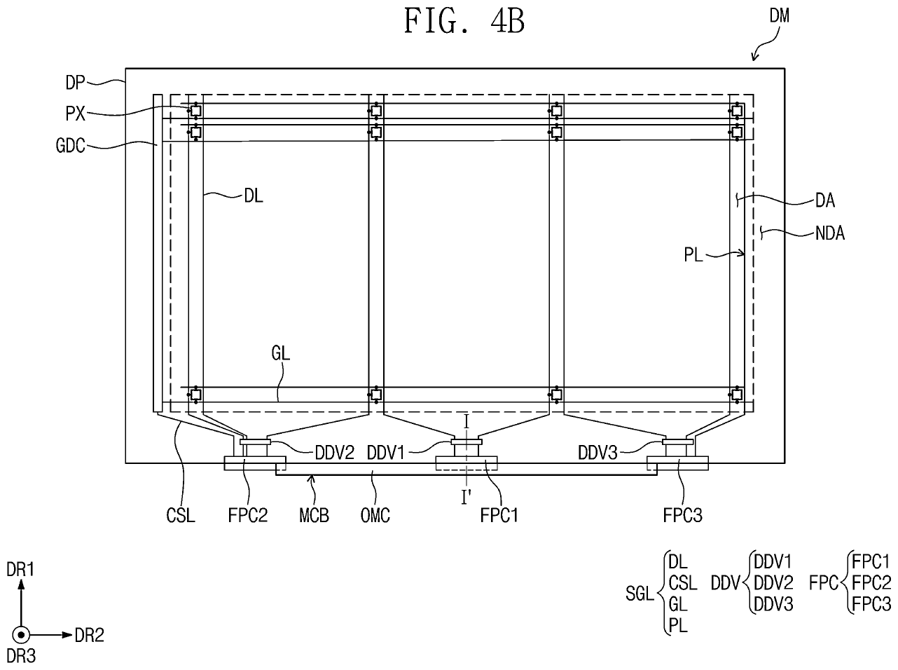

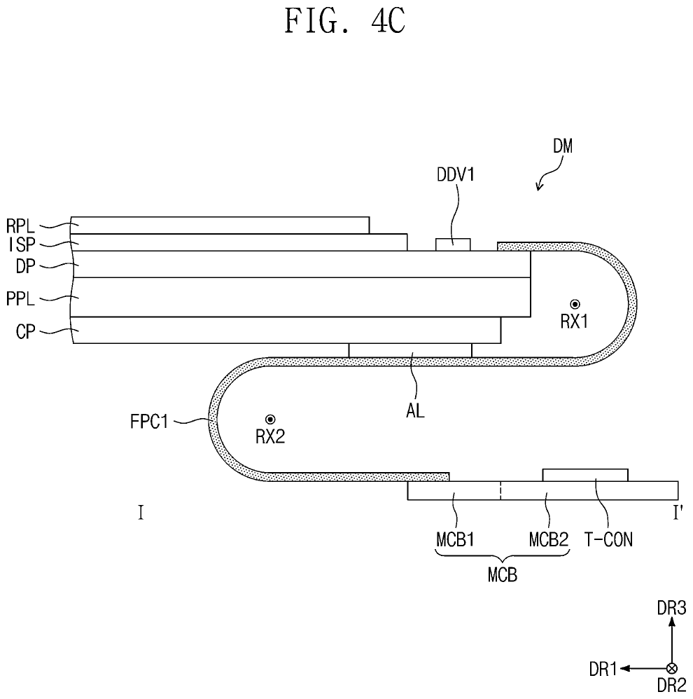

FIGS. 4A to 4C are plan views of the display panel illustrated in FIG. 3.

FIG. 4A is a view of a state before flexible circuit boards FPC and a main circuit board MCB connected to the display panel DP are bent, and FIG. 4B is a view of a state in which the flexible circuit boards FPC and the main circuit board MCB connected to the display panel DP are bent. FIG. 4C is a cross-sectional view along line I-I′ illustrated in FIG. 4B.

Referring to FIG. 4A, the display device DD may include the flexible circuit boards FPC, the main circuit board MCB, and the display module DM. The display module DM may include the display panel DP, a scan driver GDC, a plurality of signal lines SGL, a plurality of data drivers DDV, and a plurality of pixels PX.

The display panel DP may include the display area DA and the non-display area NDA proximate to the display area DA. The non-display area NDA may at least partially surround the display area DA. The display area DA may be an area that displays an image, and the non-display area NDA may be an area that does not display an image.

The data drivers DDV may be arranged in the non-display area NDA of the display panel DP. The data drivers DDV may be arranged adjacent to an edge of the display panel DP. The data drivers DDV may be arranged in the second direction DR2.

The data drivers DDV may include a first data driver DDV1, a second data driver DDV2, and a third data driver DDV3. In a plan view, the first data driver DDV1 may overlap a central area of the display panel DP.

The second data driver DDV2 may be spaced apart from the first data driver DDV1 in the second direction DR2. In a plan view, the second data driver DDV2 may be disposed on a left side of the first data driver DDV1.

The third data driver DDV3 may be spaced apart from the first data driver DDV1 in the second direction DR2. In a plan view, the third data driver DDV3 may be disposed on a right side of the first data driver DDV1. For example, the first data driver DDV1 may be dispose between the second and the third data drivers DDV2 and DDV3.

The first, second and third data drivers DDV1, DDV2 and DDV3 may be mounted on the display panel DP. Each of the first, second and third data drivers DDV1, DDV2 and DDV3 may be electrically connected to the display panel DP and provide an electrical signal to the display panel DP.

The flexible circuit boards FPC may be connected to the display panel DP. One ends of the flexible circuit boards FPC may be arranged in a peripheral area of the display panel DP. For example, the flexible circuit boards FPC may be arranged adjacent to the edge of the display panel DP.

The flexible circuit boards FPC may be arranged on pads arranged on the display panel DP. The flexible circuit boards FPC may be electrically connected to the pads through an anisotropic conductive adhesive layer. Accordingly, the flexible circuit boards FPC may be electrically connected to the display panel DP through the pads.

The flexible circuit boards FPC may include a first flexible circuit board FPC1, a second flexible circuit board FPC2, and a third flexible circuit board FPC3. In a plan view, the first flexible circuit board FPC1 may overlap the central area of the display panel DP.

The second flexible circuit board FPC2 may be spaced apart from the first flexible circuit board FPC1 in the second direction DR2. In a plan view, the second flexible circuit board FPC2 may be disposed on a left side of the first flexible circuit board FPC1.

The third flexible circuit board FPC3 may be spaced apart from the first flexible circuit board FPC1 in the second direction DR2. In a plan view, the third flexible circuit board FPC3 may be disposed on a right side of the first flexible circuit board FPC1. For example, the first flexible circuit board FPC1 may be disposed between the second and the third circuit boards FPC2 and FPC3.

The first flexible circuit board FPC1 may be spaced apart from the first data driver DDV1 in the first direction DR1. The second flexible circuit board FPC2 may be spaced apart from the second data driver DDV2 in the first direction DR1. The third flexible circuit board FPC3 may be spaced apart from the third data driver DDV3 in the first direction DR1. For example, the data drivers DDV1, DDV2 and DDV3 may be disposed vertically above the flexible circuit boards FPC1, FPC2 and FPC3.

Each of the flexible circuit boards FPC may be connected to a corresponding data driver DDV by data lines DL, which will be described below.

Although the three flexible circuit boards FPC and the three data drivers DDV are illustrated in FIG. 4A, the number of the flexible circuit boards FPC and the number of the data drivers DDV are not necessarily limited thereto.

The main circuit board MCB may be connected to the flexible circuit boards FPC. A side of the flexible circuit boards FPC located in the opposite to the first direction DR1 may be connected to the main circuit board MCB. For example, the sides of the flexible circuit boards FPC in connection with the main circuit boards MCB are opposite to the sides of the flexible circuit boards FPC which are connected to the display panel DP. The main circuit board MCB may be electrically connected to the display panel DP through the flexible circuit boards FPC.

The main circuit board MCB may include a first board MCB1 and a second board MCB2. The flexible circuit boards FPC may be connected to an edge of the first board MCB1 facing the display panel DP.

The second board MCB2 may extend from the first board MCB1 in the first direction DR1. The first board MCB1 and the second board MCB2 may be integrally formed.

In a plan view, the main circuit board MCB may have a “′T” shape. A width of the main circuit board MCB in the second direction DR2 may vary.

A length of the first board MCB1 in the second direction DR2 may be greater than a length of the second board MCB2 in the second direction DR2. A length of the first board MCB1 in the first direction DR1 may be shorter than a length of the second board MCB2 in the first direction DR1. However, this is exemplary, and the lengths of the first board MCB1 and the second board MCB2 in the first direction DR1 and the second direction DR2 may vary.

A voltage generating unit may be disposed on the main circuit board MCB. The main circuit board MCB may generate voltages for operation of the display panel DP.

The scan driver GDC may generate a plurality of scan signals and output the scan signals to a plurality of scan lines GL, which will be described below. The scan driver GDC may further output another control signal to driving circuits of the pixels PX.

The scan driver GDC may include a plurality of transistors TR formed through the same process as the data drivers DDV for the pixels PX such as a low temperature polycrystalline silicon (LTPS) process or a low temperature polycrystalline oxide (LTPO) process.

The signal lines SGL may include the scan lines GL, the data lines DL, a power line PL, and a control signal line CSL. The scan lines GL may extend in the opposite to the second direction DR2 and connect to the scan driver GDC. Each of the scan lines GL, data lines DL and the power line PL may connect to a corresponding pixel PX. The control signal line CSL may be connected to the scan driver GDC and provide control signals.

The data lines DL may be connected to the data drivers DDV and the flexible circuit boards FPC as it extends in the opposite to the first direction DR1. The data lines DL may be electrically connected to the data drivers DDV and the flexible circuit boards FPC through the pads.

The power line PL may be electrically connected to the third flexible circuit board FPC3 and the main circuit board MCB. Additionally, the power line PL may be electrically connected to the voltage generating unit in the main circuit board MCB and may provide a reference voltage to the pixels PX.

The control signal line CSL may be connected to the scan driver GDC. Additionally, the control signal line CSL may be electrically connected to the second flexible circuit board FPC2 and the main circuit board MCB through the pads.

The main circuit board MCB may include a timing controller T-CON. The timing controller T-CON may be disposed on the second board MCB2, and may be spaced apart from the first flexible circuit board FPC1 in the first direction DR1.

The timing controller T-CON may control operations of the scan driver GDC and the data drivers DDV. The timing controller T-CON may generate a scan control signal and a data control signal in response to control signals received from an external unit.

The scan control signal may be provided to the scan driver GDC through the control signal line CSL. The data control signal may be provided to the data driver DDV. The timing controller T-CON may receive image signals from an external unit, convert data formats of the image signals to satisfy interface specifications with the data driver DDV, and provide the converted image signals to the data driver DDV.

The scan driver GDC may generate the plurality of scan signals in response to the scan control signal. The scan signals may be applied to the pixels PX through the scan lines GL. The scan signals may be sequentially applied to the pixels PX.

The data drivers DDV may generate a plurality of data voltages corresponding to the image signals in response to the data control signal. The data voltages may be applied to the pixels PX through the data lines DL.

The pixels PX may receive the data voltages in response to the scan signals. The pixels PX may display an image by emitting light having luminance corresponding to the data voltages.

Referring to FIGS. 4B and 4C, the display module DM may further include a cover panel CP. The cover panel CP may be disposed under the panel protecting layer PPL. The cover panel CP may be bonded to the panel protecting layer PPL through an adhesive layer. The cover panel CP may support a rear surface of the display panel DP. The rear surface of the display panel DP may be defined as a surface opposite to an upper surface, on which the input sensing unit ISP is disposed.

Edges of the input sensing unit ISP, the reflection preventing layer RPL, and the cover panel CP may be arranged within edges of the display panel DP and the panel protecting layer PPL. The display panel DP and the panel protecting layer PPL may have the same width.

According to an embodiment of the present disclosure, the flexible circuit boards FPC may be bent with respect to imaginary axes which is parallel to the second direction DR2, so that the main circuit board MCB is disposed under the display panel DP.

For example, as illustrated in FIG. 4C, the first flexible circuit board FPC1 may be bent twice with respect to a first bending axis RX1 and a second bending axis RX2. For example, the first flexible circuit board FPC1 may have an inverted “S” shape in a left-right direction. However, this is exemplary, and the number of the bending axes may be one or three or more.

The second and third flexible circuit boards FPC2 and FPC3 may have substantially the same shape and may also be bent.

When the flexible circuit board FPC is bent, a portion of the flexible circuit board FPC may be disposed under the cover panel CP. For example, as illustrated in FIG. 4C, an adhesive layer AL may be disposed between the first flexible circuit board FPC1 and the cover panel CP. The first flexible circuit board FPC1 and the cover panel CP may be bonded to each other through the adhesive layer AL. The second and third flexible circuit boards FPC2 and FPC3 and the cover panel CP may be bonded to each other through the adhesive layer AL.

When the flexible circuit boards FPC are bent, the main circuit board MCB may be disposed under the display panel DP. A top surface of the first board MCB1 may face a bottom surface of the cover panel CP. In a plan view, a portion of the second board MCB2 may be exposed to the outside of the display panel DP. Hereinafter, the portion of the second board MCB2 which is exposed to the outside of the display panel DP in a plan view, may be defined as an exposure board OMC.

FIG. 5 is a view exemplarily illustrating a cross section of a display module corresponding to any one pixel illustrated in FIG. 4A.

Referring to FIG. 5, the pixel PX may include a transistor TR and a light emitting element OLED. The light emitting element OLED may include a first electrode AE (or an anode), a second electrode CE (or a cathode), a hole control layer HCL, an electron control layer ECL, and a light emitting layer EML. The transistor TR and the light emitting element OLED may be arranged on the substrate SUB. Although one transistor TR is exemplarily illustrated, the pixel PX may include a plurality of transistors TR and one or more capacitors for driving the light emitting element OLED.

The display area DA may include a light emitting area PA corresponding to each of the pixels PX and a non-light emitting area NPA next to the light emitting area PA. For example, the light emitting area PA may be disposed between the non-light emitting area NPA. The light emitting element OLED may be disposed in the light emitting area PA.

A buffer layer BFL may be disposed on the substrate SUB, and the buffer layer BFL may be an inorganic layer. A semiconductor pattern may be disposed on the buffer layer BFL. The semiconductor pattern may include polysilicon, amorphous silicon, or metal oxide.

The semiconductor pattern may be doped with an N-type dopant or a P-type dopant. The semiconductor pattern may include a high-doped area and a low-doped area. Conductivity of the high-doped area is higher than that of the low-doped area and may serve as a source electrode and a drain electrode of the transistor TR. The low-doped area may correspond to an active area (or a channel) of a transistor TR.

A source area “S,” an active area “A,” and a drain area “D” of the transistor TR may be formed from the semiconductor pattern. A first insulating layer INS1 may be disposed on the semiconductor pattern. A gate “G” of the transistor TR may be disposed on the first insulating layer INS1. A second insulating layer INS2 may be disposed on the gate “G”. For example, the second insulating layer INS2 may at least partially surround the gate “G”. A third insulating layer INS3 may be disposed on the second insulating layer INS2.

A connection electrode CNE may include a first connection electrode CNE1 and a second connection electrode CNE2 to connect the transistor TR and the light emitting element OLED. The first connection electrode CNE1 may be disposed on the third insulating layer INS3 and may be vertically connected to the drain area “D” through a first contact hole CH1 defined by the first to third insulating layers INS1 to INS3. For example, the first connection electrode CNE1 may extend from the top surface of the third insulating layer INS3 and penetrate the first to third insulating layers INS1 to INS3 through the first contact hole CH1.

A fourth insulating layer INS4 may be disposed on the first connection electrode CNE1. For example, the fourth insulating layer INS4 may at least partially cover the first connection electrode CNE1. A fifth insulating layer INS5 may be disposed on the fourth insulating layer INS4. The second connection electrode CNE2 may be disposed on the fifth insulating layer INS5. The second connection electrode CNE2 may be vertically connected to the first connection electrode CNE1 through a second contact hole CH2 defined by the fourth and fifth insulating layers INS4 and INS5. For example, the second connection electrode CNE2 may extend from the top surface of the fifth insulating layer INS5 and penetrate the fourth and fifth insulating layers INS4 and INS5 through the second contact hole CH2.

A sixth insulating layer INS6 may be disposed on the second connection electrode CNE2. For example, the sixth insulating layer INS5 may at least partially surround the second connection electrode CNE2. The circuit element layer DP-CL may include layers between the buffer layer BFL and the sixth insulating layer INS6. The first insulating layer INS1 to the sixth insulating layer INS6 may be inorganic layers or organic layers.

The first electrode AE may be disposed on the sixth insulating layer INS6. The first electrode AE may be connected to the second connection electrode CNE2 through a third contact hole CH3 defined by the sixth insulating layer INS6. For example, the first electrode AE may extend from the top surface of the sixth insulating layer INS6 and penetrate the sixth insulating layer INS6 through the third contact hole CH3. A pixel defining film PDL, in which an opening PX_OP for exposing a predetermined portion of the first electrode AE is defined, may be disposed on the first electrode AE and the sixth insulating layer INS6. For example, the pixel defining film PDL may at least partially surround the first electrode AE and the sixth insulating layer INS6.

The hole control layer HCL may be disposed on the first electrode AE and the pixel defining film PDL. The hole control layer HCL may contact the opening PX_OP. The hole control layer HCL may include a hole transport layer and a hole injection layer.

The light emitting layer EML may be disposed on the hole control layer HCL. The light emitting layer EML may be disposed in an area corresponding to the opening PX_OP. The light emitting layer EML may include an organic material and/or an inorganic material. The light emitting layer EML may generate any one of red, green, and blue light.

The electron control layer ECL may be disposed on the light emitting layer EML and the hole control layer HCL. The electron control layer ECL may include an electron transport layer and an electron injection layer. The hole control layer HCL and the electron control layer ECL may be commonly arranged in the light emitting area PA and the non-light emitting area NPA.

The second electrode CE may be disposed on the electron control layer ECL. The second electrode CE may be commonly disposed in the pixels PX. Layers, on which the light emitting element OLED is disposed, may be defined as the display element layer DP-OLED.

The thin film encapsulation layer TFE may include a first encapsulation layer EN1 disposed on the second electrode CE, a second encapsulation layer EN2 disposed on the first encapsulation layer EN1, and a third encapsulation layer EN3 disposed on the second encapsulation layer EN2. The thin film encapsulation layer TFE may be disposed on the second electrode CE to cover the pixel PX.

The first and third encapsulation layers EN1 and EN3 may include inorganic insulating layers and protect the pixel PX from moisture/oxygen. The second encapsulation layer EN2 may include an organic insulating layer and protect the pixel PX from foreign substances such as dust particles.

A first voltage may be applied to the first electrode AE through the transistor TR, and a second voltage with a lower voltage level than that of the first voltage may be applied to the second electrode CE. Holes and electrons injected into the light emitting layer EML are coupled to each other to form excitons, and as the excitons transition to a ground state, the light emitting element OLED may emit light.

The input sensing unit ISP may be disposed on the thin film encapsulation layer TFE. The input sensing unit ISP may be directly manufactured on an upper surface of the thin film encapsulation layer TFE.

A base layer BS may be disposed on the thin film encapsulation layer TFE. The base layer BS may include an inorganic insulating layer. At least one inorganic insulating layer of the base layer BS may be provided on the thin film encapsulation layer TFE.

The input sensing unit ISP may include a first conductive pattern CTL1 and a second conductive pattern CTL2 disposed on the first conductive pattern CTL1. The first conductive pattern CTL1 may be disposed on the base layer BS. An insulating layer TINS may be disposed on the base layer BS to cover at least partially the first conductive pattern CTL1. The insulating layer TINS may include an inorganic insulating layer or an organic insulating layer. The second conductive pattern CTL2 may be disposed on the insulating layer TINS. For example, the second conductive pattern CTL2 may extend from a top surface of the insulating layer TINS and vertically extend to connect with the first conductive pattern CTL1.

The first and second conductive patterns CTL1 and CTL2 may overlap at the non-light emitting area NPA. The first and second conductive patterns CTL1 and CTL2 may be arranged in the non-light emitting area NPA between the light emitting areas PA and have a mesh shape.

The first and second conductive patterns CTL1 and CTL2 may form sensors of the input sensing unit ISP. For example, the first and second conductive patterns CTL1 and CTL2 having a mesh shape may be separated from each other in a predetermined area to form sensors. A portion of the second conductive pattern CTL2 may be connected to the first conductive pattern CTL1.

The reflection preventing layer RPL may include a black matrix BM and a plurality of color filters CF. The reflection preventing layer RPL may be disposed on the second conductive pattern CTL2. The black matrix BM may overlap the non-light emitting area NPA, and the color filters CF may overlap the light emitting areas PA.

The black matrix BM may be disposed on the insulating layer TINS and cover the second conductive pattern CTL2. An opening B_OP overlapping the light emitting area PA and the opening PX_OP may be defined in the black matrix BM. The black matrix BM may absorb and block a light. A width of the opening B_OP may be greater than a width of the opening PX_OP.

The color filters CF may be arranged on the insulating layer TINS and the black matrix BM. For example, the color filters may at least partially cover the insulating layer TINS and the black matrix BM. The color filters CF may be arranged in the openings B_OP, respectively. A planarization insulating layer PINS may be disposed on the color filters CF. The planarization insulating layer PINS may provide a flat upper surface.

When an external light moving toward the display panel DP is reflected by the display panel DP and provided back to an external user, the user may visually perceive the external light like a mirror effect. To prevent this phenomenon, the reflection preventing layer RPL may include a plurality of color filters CF that display the same colors as those of the pixels PX of the display panel DP. The color filters CF may filter the external light into the same colors as those of the pixels PX. Thus, the user may not perceive the external light.

However, an embodiment of the present disclosure is not necessarily limited thereto, and the reflection preventing layer RPL may include a polarizing film to reduce reflectance of the external light. The polarizing film may be separately manufactured and attached to the input sensing unit ISP by an adhesive layer. The polarizing film may include a phase retarder and/or a polarizer.

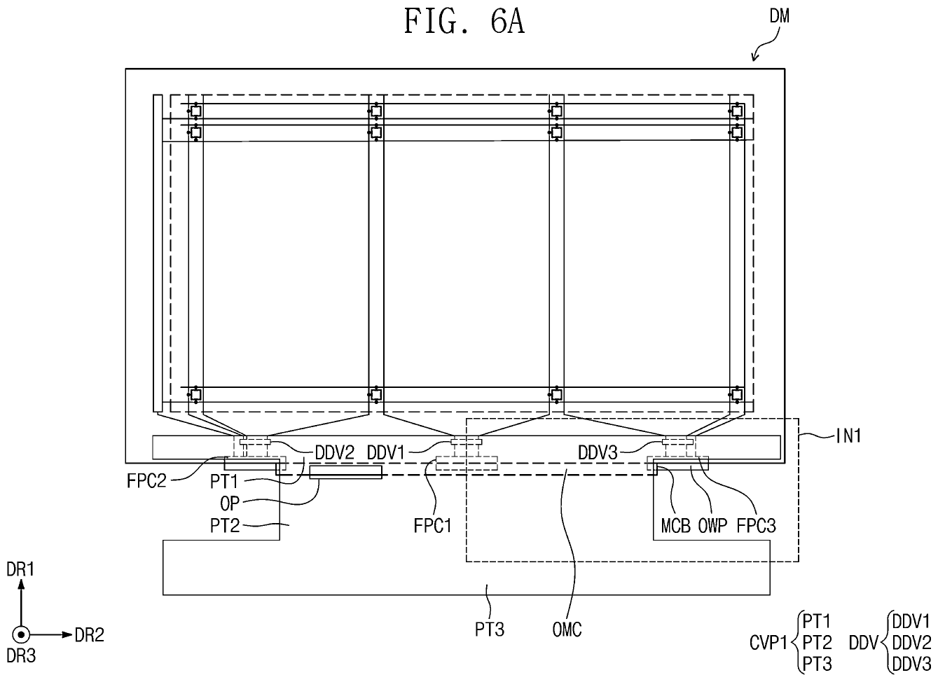

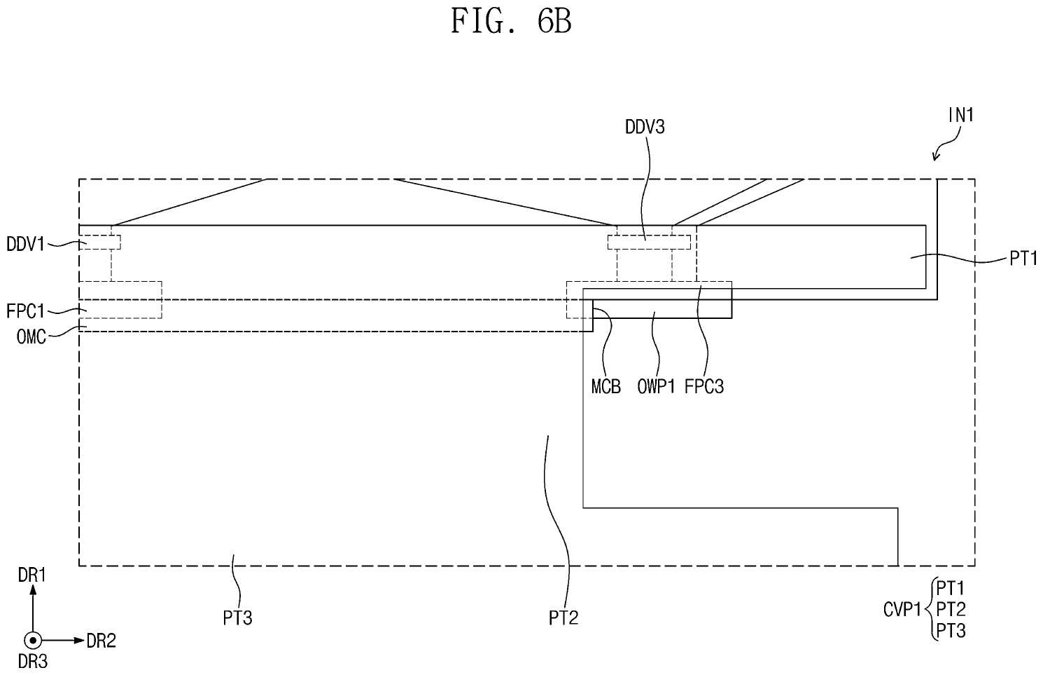

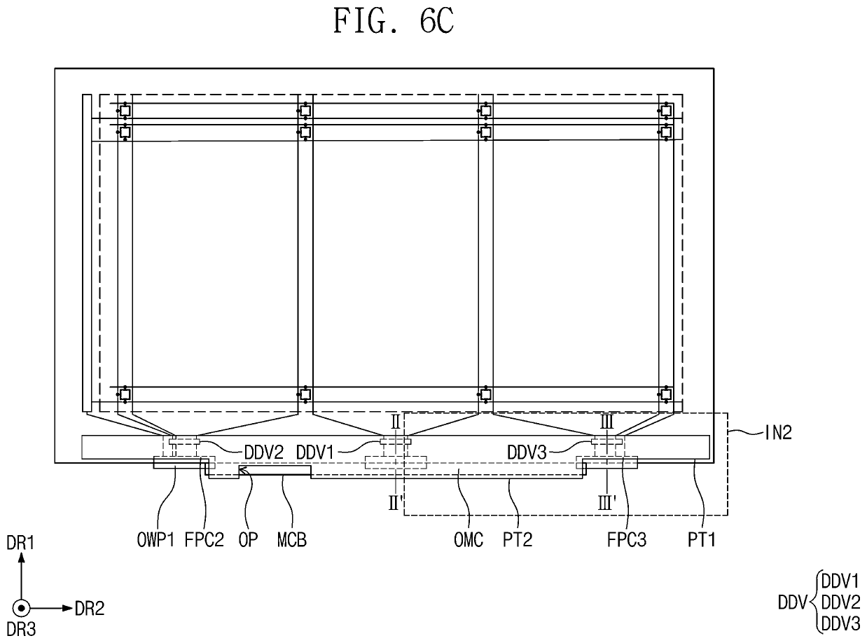

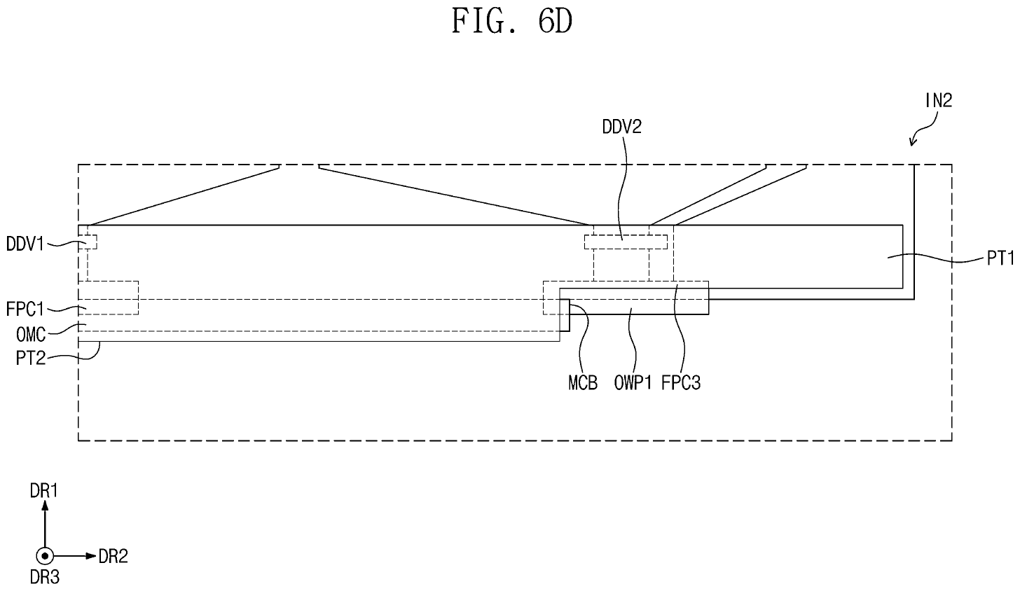

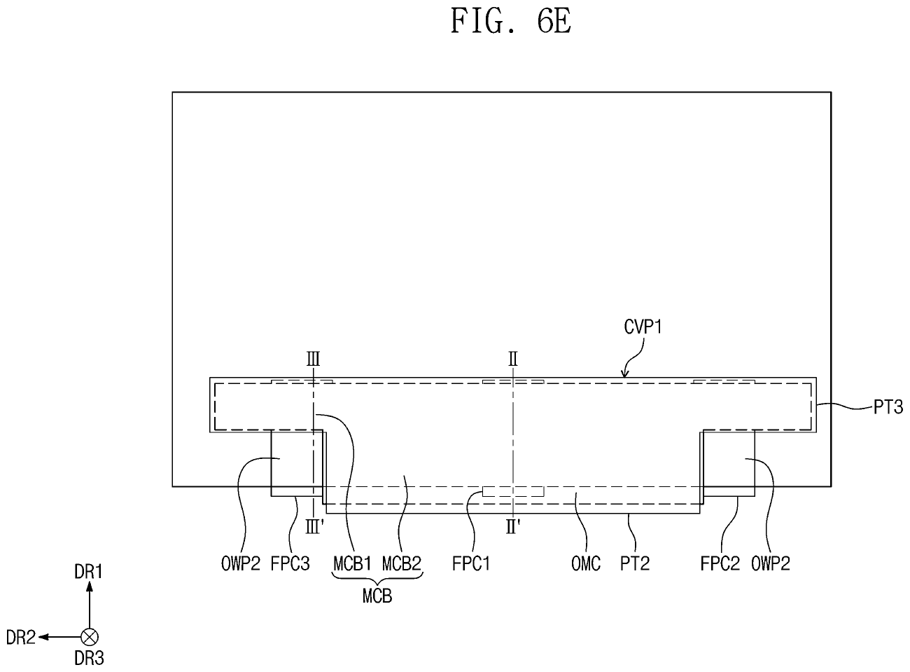

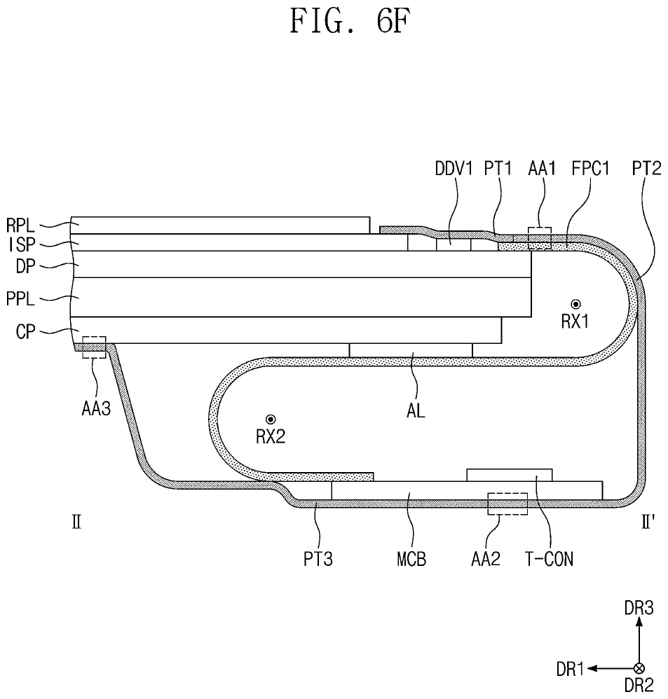

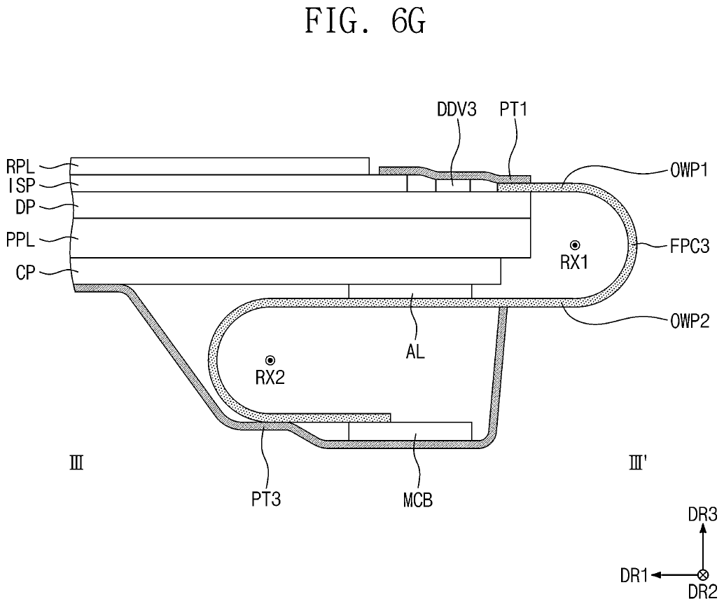

FIGS. 6A to 6G are views for describing a first cover.

FIGS. 6A to 6E are plan views, FIG. 6F is a cross-sectional view along line II-II′ illustrated in FIG. 6C, and FIG. 6G is a cross-sectional view along line III-III′ illustrated in FIG. 6C.

FIGS. 6A and 6B are views illustrating a first cover CVP1 before being bent, and FIGS. 6C to 6G are views illustrating the bent first cover CVP1.

FIG. 6E is a plan view viewed from a lower surface of the display panel DP.

FIG. 6B is an enlarged plan view of a first enlarged area IN1 illustrated in FIG. 6A, and FIG. 6D is an enlarged plan view of a second enlarged area IN2 illustrated in FIG. 6C.

The flexible circuit boards FPC of FIGS. 6C to 6G are illustrated in a bent state.

The display module DM, the flexible circuit boards FPC, and the main circuit board MCB of FIGS. 6A to 6G are the same as the display module DM, the flexible circuit boards FPC, and the main circuit board MCB of FIGS. 4A and 4B, and thus a description thereof will be omitted or simplified.

Referring to FIGS. 6A and 6B, the display device DD (see FIG. 1) may further include the first cover CVP1. The first cover CVP1 may include a first part PT1, a second part PT2, and a third part PT3. The first part PT1 may be disposed on portions of the data drivers DDV and the first, second, and third flexible circuit boards FPC1, FPC2, and FPC3.

A side of the first part PT1 may overlap portions of the flexible circuit boards FPC1, FPC2, and FPC3. For example, the bottom surface of the first part PT1 may contact the top surfaces of the flexible circuit boards FPC1, FPC2, and FPC3. The second part PT2 may extend in an opposite to the first direction DR1 from the first part PT1. The second part PT2 may be disposed on other portions of the first flexible circuit board FPC1, which do not overlap the first part PT1, and the exposure board OMC of the main circuit board MCB. In a plan view, the second part PT2 may cover the exposure board OMC.

In a plan view, as illustrated in FIG. 6B, the first part PT1 and the second part PT2 may cover some portions of the third flexible circuit board FPC3 and a portion of the second flexible circuit board FPC2. In a plan view, some other portions of the second flexible circuit board FPC2 and the other portion of the third flexible circuit board FPC3 may be exposed to the outside of the first part PT1 and the second part PT2. Hereinafter, the portions of the second flexible circuit board FPC2 and the third flexible circuit board FPC3 exposed to the outside may be defined as first exposure parts OWP1.

The third part PT3 may extend in an opposite to the first direction DR1 from the second part PT2.

In a plan view, the first cover CVP1 may have a dumbbell shape. The dumbbell shape may refer to a form that includes two parallel planes connected by a central section in between. In detail, in a plan view, a length of the first part PT1 in the second direction DR2 may be greater than a length of the second part PT2 in the second direction DR2. The length of the first part PT1 in the second direction DR2 may be greater than a length of the third part PT3 in the second direction DR2. The length of the third part PT3 in the second direction DR2 may be greater than the length of the second part PT2 in the second direction DR2. That is, the length of the second part PT2 in the second direction DR2 may be shortest, and the length of the first part PT1 in the second direction DR2 may be longest.

The length of the second part PT2 in the second direction DR2 may be shorter than a length of the exposure board OMC of the main circuit board MCB in the second direction DR2. As illustrated in FIG. 6B, both ends of the exposure board OMC in the second direction DR2, which are opposite to each other, may be exposed to the outside of the second part PT2.

Referring to FIGS. 6F and 6G, the first cover CVP1 may be disposed on the input sensing unit ISP. The first cover CVP1 may be disposed on an edge of the input sensing unit ISP, which is adjacent to the data drivers DDV. The first cover CVP1 may be coupled to the input sensing unit ISP through an adhesive layer. However, this is exemplary, and the first cover CVP1 may be disposed on the reflection preventing layer RPL.

Referring to FIGS. 6C, 6D, 6F, and 6G, the first cover CVP1 may be bent and cover the first flexible circuit boards FPC1, the data drivers DDV, and the main circuit board MCB. The first cover CVP1 may be bent with a predetermined curvature.

Portions of the first part PT1 and the second part PT2 may be arranged on the display panel DP. On the display panel DP, the first part PT1 may cover portions of the data drivers DDV and the first, second, and third flexible circuit boards FPC1, FPC2, and FPC3. On the display panel DP, the portion of the second part PT2 may cover the remaining portion of the first flexible circuit board FPC1, which is not covered by the first part PT1, and the exposure board OMC.

Referring to FIGS. 6E, 6F, and 6G, the remaining portion of the second part PT2 and the third part PT3 may be arranged under the display panel DP. As illustrated in FIGS. 6E and 6F, under the display panel DP, the second part PT2 may cover the main circuit board MCB and the first flexible circuit boards FPC1. As illustrated in FIGS. 6E and 6G, under the display panel DP, the second part PT2 and the third part PT3 may not cover the portion of the second flexible circuit board FPC2 and the portion of the third flexible circuit board FPC3.

In detail, the second part PT2 may cover the second board MCB2 of the main circuit board MCB. In this case, the length of the second part PT2 in the second direction DR2 is shorter than the length of the second board MCB2 in the second direction DR2. Thus, as illustrated in FIG. 6E, both ends of the second board MCB2, which are opposite to each other in the second direction DR2, may be exposed to the outside of the second part PT2.

As illustrated in FIG. 6E, the length of the second part PT2 in the second direction DR2 may be smaller than a length from a side of the second flexible circuit board FPC2 to a side of the third flexible circuit board FPC3. Accordingly, the portion of the second flexible circuit board FPC2 and the portion of the third flexible circuit board FPC3 may be exposed to the outside of the first cover CVP1. Portions of the second flexible circuit board FPC2 and the third flexible circuit board FPC3 arranged under the display panel DP and exposed to the outside of the first cover CVP1 may be defined as second exposure parts OWP2.

Lengths of the third part PT3 in the first direction DR1 and the second direction DR2 may be greater than lengths of the first board MCB1 in the first direction DR1 and the second direction DR2. That is, an area of the third part PT3 may be greater than an area of the first board MCB1. Accordingly, the third part PT3 may completely cover the first board MCB1 disposed under the display panel DP.

As illustrated in FIGS. 6F and 6G, the second part PT2 may be in contact with a lower surface of the main circuit board MCB. The third part PT3 may be in contact with the lower surface of the cover panel CP.

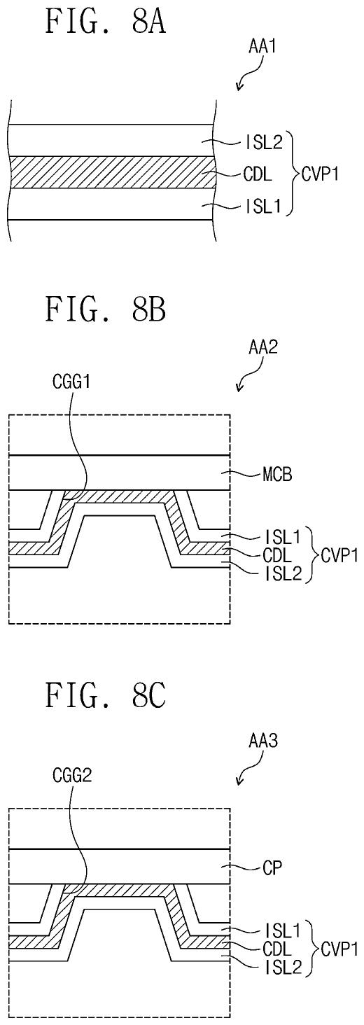

The second part PT2 may be grounded to the main circuit board MCB, and the third part PT3 may be grounded to the cover panel CP. The grounding of the second part PT2 and the third part PT3 will be described in detail with reference to FIGS. 8B and 8C.

The first cover CVP1 may cover portions of the flexible circuit board FPC, the data drivers DDV, and the main circuit board MCB, thereby shielding static electricity. Further, the first cover CVP1 may block noise generated in the vicinity of the data drivers DDV, the flexible circuit board FPC, and the main circuit board MCB.

Referring to FIGS. 6A and 6C, a connection opening OP may be defined in the first cover CVP1. The connection opening OP may overlap a portion of the main circuit board MCB exposed to the outside of the display panel DP. A connector disposed on the main circuit board MCB may be exposed to the outside of the first cover CVP1 by the connection opening OP. The connector exposed to the outside may be connected to a main processor of a laptop computer, a mobile phone, or the like.

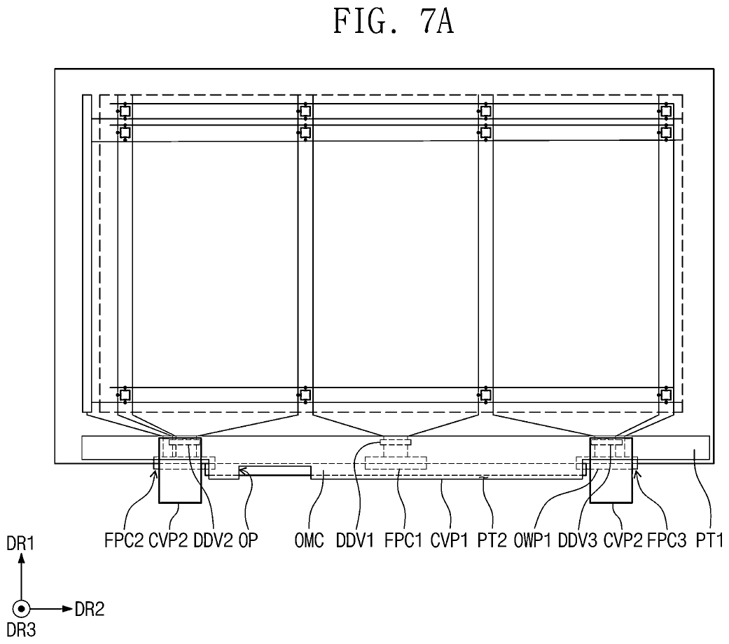

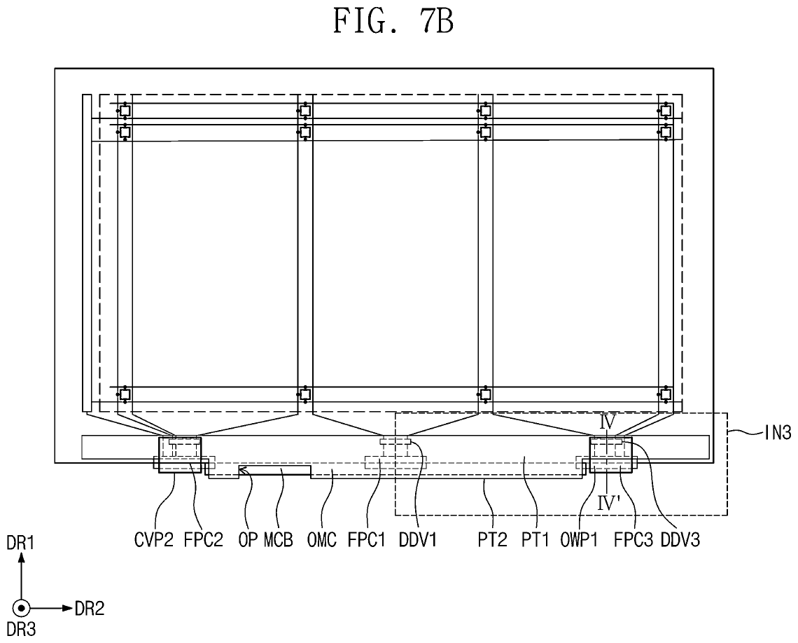

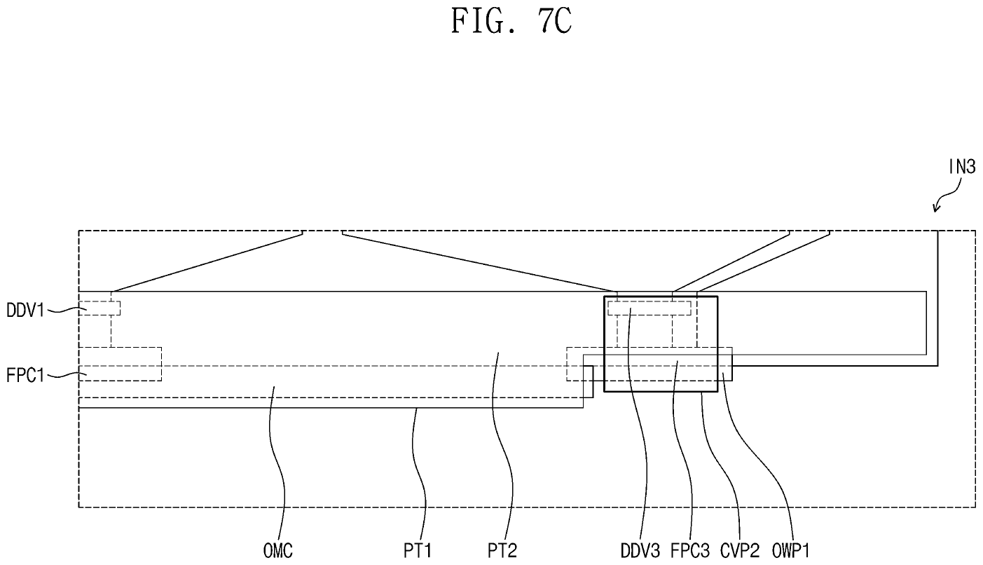

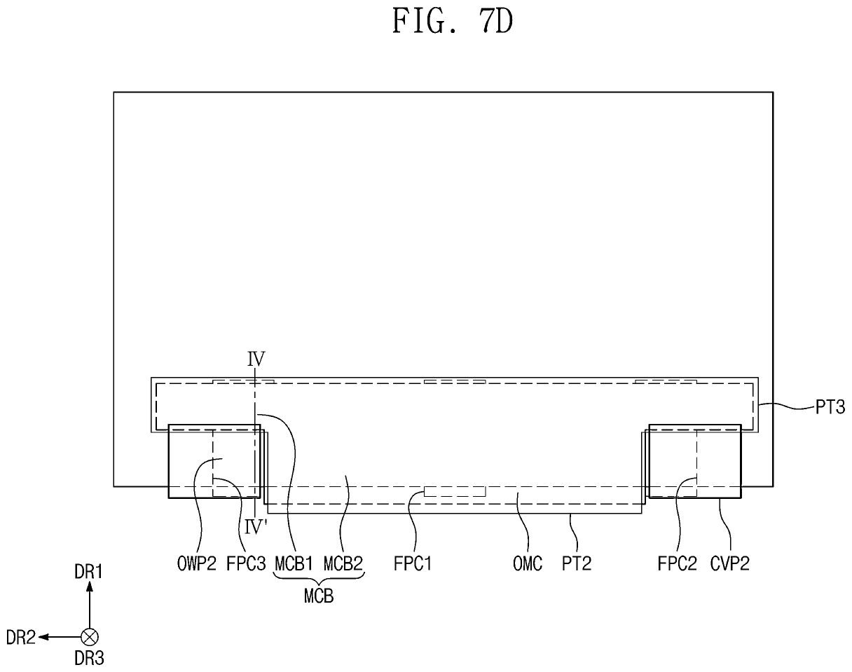

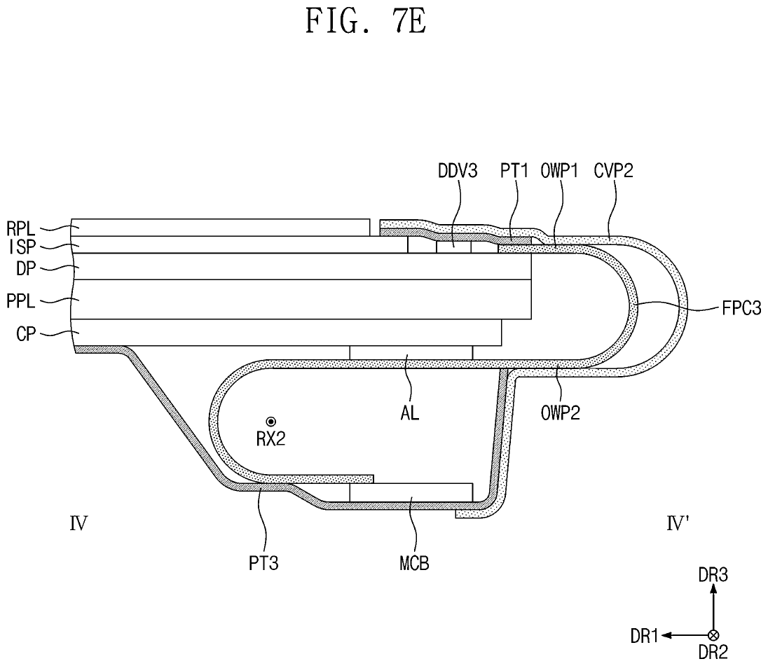

FIGS. 7A to 7E are views for describing second cover.

FIGS. 7A and 7D are plan views, and FIG. 7E is a cross-sectional view along line IV-IV′ illustrated in FIG. 7B.

FIG. 7C is an enlarged plan view of a third enlarged area IN3 of FIG. 7B.

FIG. 7A is a view illustrating second cover CVP2 before being bent, and FIGS. 7B and 7E are views illustrating the bent second cover CVP2.

FIG. 7D is a plan view viewed from the lower surface of the display panel DP.

The flexible circuit boards FPC of FIGS. 7A to 7D are illustrated in a bent state.

The display module DM, the flexible circuit boards FPC, the main circuit board MCB, and the first cover CVP1 of FIGS. 7A to 7E are the same as the display module DM, the flexible circuit boards FPC, the main circuit board MCB, and the first cover CVP1 illustrated in FIGS. 4A and 6A to 6C, and thus a description thereof will be omitted or simplified.

Referring to FIG. 7A, the display device DD (see FIG. 1) may further include the second cover CVP2. In a plan view, the second cover CVP2 may be arranged on the first part PT1 of the first cover CVP1.

The second cover CVP2 may be spaced apart from each other in the second direction DR2. In a plan view, the second cover CVP2 may be arranged adjacent to both ends of the second part PT2, which are opposite to each other in the second direction DR2. The second part PT2 may be disposed between the second cover CVP2.

In a plan view, the second cover CVP2 may overlap the second data driver DDV2 and the third data driver DDV3. The second cover CVP2 may overlap the second flexible circuit board FPC2 and the third flexible circuit board FPC3. The second cover CVP2 may overlap the first exposure parts OWP1.

In a plan view, the second cover CVP2 may be a rectangular shape. However, the present disclosure is not necessarily limited thereto, and the second cover CVP2 may be various shapes.

Referring to FIGS. 7B and 7E, the second cover CVP2 may be bent to cover the second flexible circuit board FPC2 and the third flexible circuit board FPC3. As illustrated in FIG. 7E, the second cover CVP2 may be bent with a predetermined curvature. For example, the curvature of the second cover CVP2 may be greater than the curvature of the first cover CVP1 illustrated in FIG. 6G. However, the present disclosure is not necessarily limited thereto, and the curvature of the first cover CVP1 may be greater than the curvature of the second cover CVP2.

Referring to FIGS. 7B to 7E, when the second cover members CVP2 are bent, some of the second cover CVP2 may be arranged on and/or under the display panel DP. The second cover CVP2 arranged under the display panel DP may extend from an edge of the display panel DP to an edge of the third part PT3.

As illustrated in FIGS. 7B and 7C, some of the second cover CVP2 arranged on the display panel DP may at least partially cover the first exposure parts OWP1. As illustrated in FIGS. 7D, some of the second cover CVP2 arranged under the display panel DP may at least partially cover the second exposure parts OWP2.

As the second cover CVP2 cover the first exposure parts OWP1 and the second exposure parts OWP2, areas of the second flexible circuit board FPC2 and the third flexible circuit board FPC3 exposed to the outside may be reduced.

Referring to FIGS. 6C, 6G, 7B, and 7E, when the first cover CVP1 covers the data drivers DDV, the flexible circuit boards FPC, and the main circuit board MCB, the first exposure parts OWP1 and the second exposure parts OWP2 of the second flexible circuit board FPC2 and the third flexible circuit board FPC3 may be exposed to the outside of the first cover CVP1.

In this case, static electricity may be generated in the first exposure parts OWP1 and the second exposure parts OWP2 exposed to the outside. The display module DM may be damaged due to the static electricity. Further, noise may be generated in the vicinity of the second flexible circuit board FPC2 and the third flexible circuit board FPC3 exposed to the outside, thereby reducing reliability of the display module DM.

However, covering the first exposure parts OWP1 and the second exposure parts OWP2 with the second cover CVP2 may reduce the exposed area. Thus, the static electricity may be prevented from being generated in the second flexible circuit board FPC2 and the third flexible circuit board FPC3, and the noise may be prevented from being generated in the vicinity of the second flexible circuit board FPC2 and the third flexible circuit board FPC3. Accordingly, the damage to the display module DM may be prevented.

FIG. 8A is a view for describing a structure of the first cover. FIG. 8B is a view for describing the first cover grounded to a main circuit board. FIG. 8C is a view for describing the first cover grounded to a cover panel.

FIG. 8A is an enlarged view of a first area AA1 illustrated in FIG. 6F, FIG. 8B is an enlarged view of a second area AA2 illustrated in FIG. 6F, and FIG. 8C is an enlarged view of a third area AA3 illustrated in FIG. 6F.

The main circuit board MCB of FIG. 8B is the same as the main circuit board MCB illustrated in FIG. 4A, and the cover panel CP illustrated in FIG. 8C is the same as the cover panel CP illustrated in FIG. 6F. Thus, a description thereof will be omitted or simplified.

Referring to FIG. 8A, the first cover CVP1 may include a first cover insulating layer ISL1, an intermediate layer CDL, and a second cover insulating layer ISL2. The first cover insulating layer ISL1 may include an insulating material such as a polymer material. For example, the polymer material may be polyethylene terephthalate (PET).

The intermediate layer CDL may be disposed on the first cover insulating layer ISL1. The intermediate layer CDL may be coupled to the first cover insulating layer ISL1 by an adhesive layer.

The intermediate layer CDL may include a conducive material such as metal. However, the present disclosure is not necessarily limited thereto, and the intermediate layer CDL may include a conductive fiber.

The first cover CVP1 may include the intermediate layer CDL, thereby shielding the static electricity. This will be described in detail in FIGS. 8B and 8C.

The second cover insulating layer ISL2 may be disposed on the intermediate layer CDL. The second cover insulating layer ISL2 may be coupled to the intermediate layer CDL by an adhesive layer.

The second cover insulating layer ISL2 may include an insulating material such as an organic material. For example, the organic material may be polyethylene terephthalate (PET). According to an embodiment, the second cover insulating layer ISL2 may be black and shield a light.

Although the configuration of the first cover CVP1 has been described in FIG. 8A, the second cover CVP2 may also have substantially the same configuration as that of the first cover CVP1.

Referring to FIGS. 6F and 8B, a first ground groove CGG1 may be defined on the lower surface of the main circuit board MCB by the first cover insulating layer ISL1. The intermediate layer CDL may be exposed from the first cover insulating layer ISL1 by the first ground groove CGG1. The exposed intermediate layer CDL may be in contact with the main circuit board MCB. The intermediate layer CDL may be connected to a wiring line disposed on the main circuit board MCB and grounded. Accordingly, the first cover CVP1 may shield the main circuit board MCB from external static electricity.

Referring to FIGS. 6F and 8C, a second ground groove CGG2 may be defined on the lower surface of the cover panel CP by the first cover insulating layer ISL1. The intermediate layer CDL may be exposed from the first ground insulating layer ISL1 by the second ground groove CGG2. The exposed intermediate layer CDL may be in contact with the cover panel CP. The intermediate layer CDL may be connected to a wiring line disposed on the cover panel CP and grounded. Accordingly, the first cover CVP1 may shield the cover panel CP from the external static electricity.

The intermediate layer CDL may be grounded to the main circuit board MCB and the cover panel CP to shield the external static electricity so as to prevent the damage to the display module DM (see FIG. 4A).

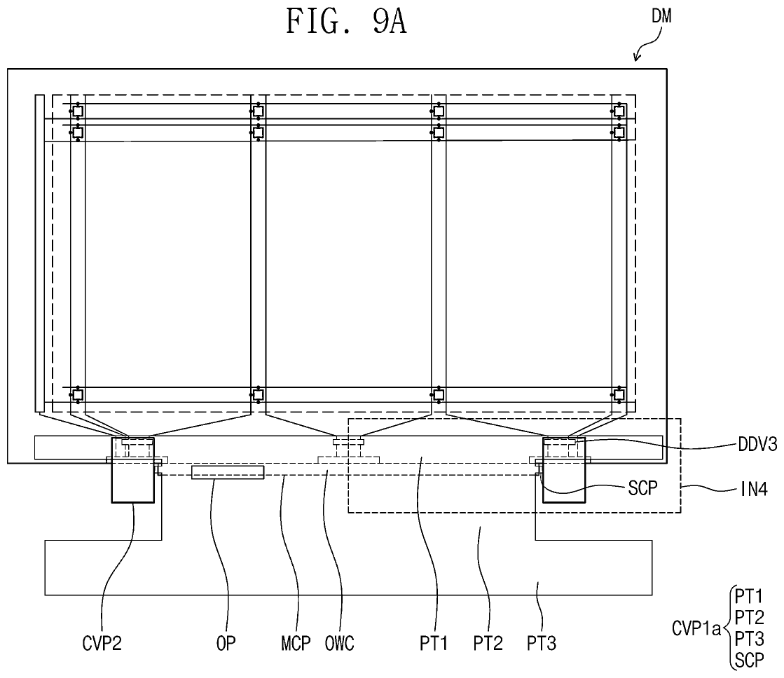

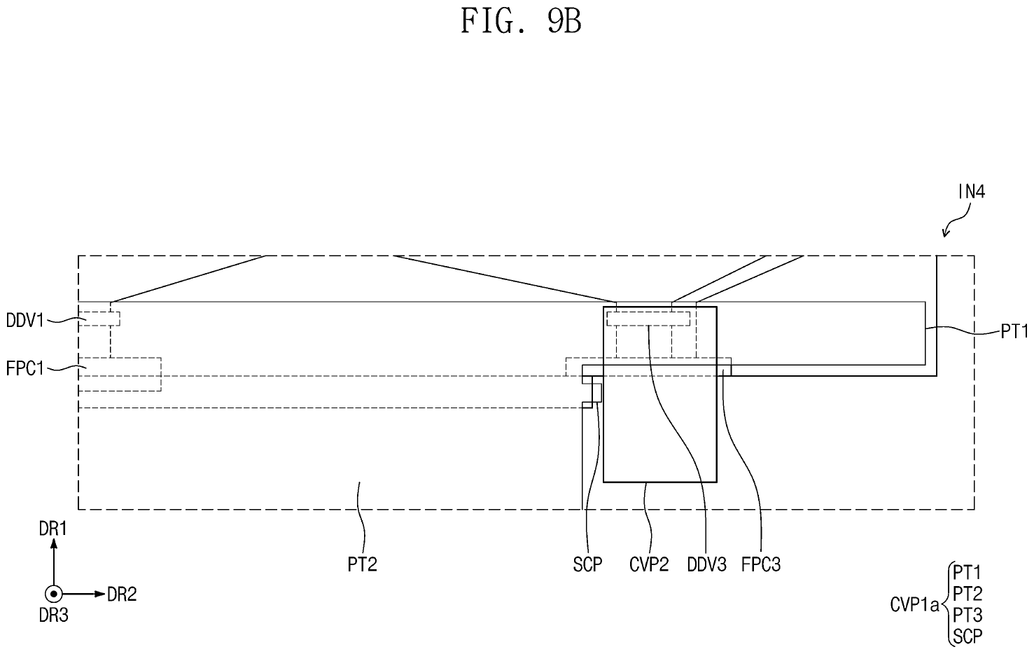

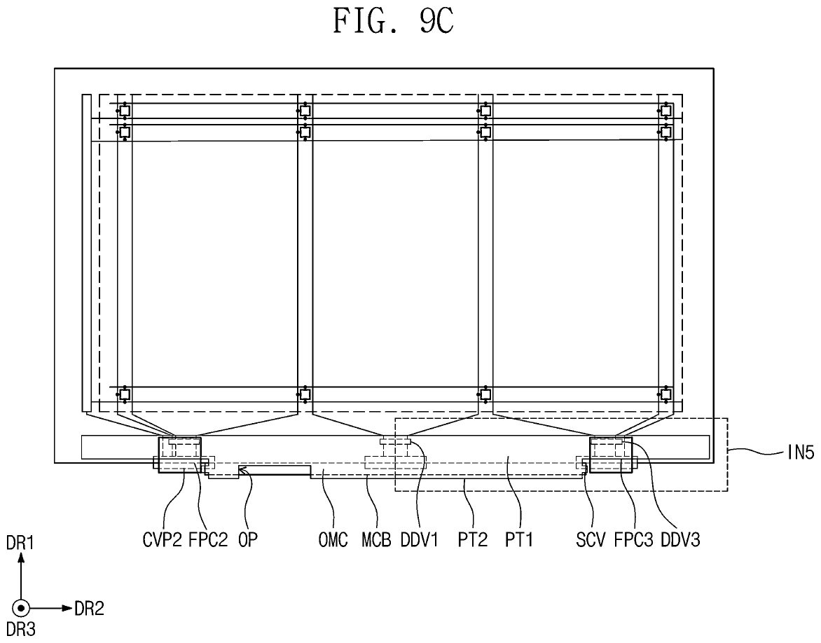

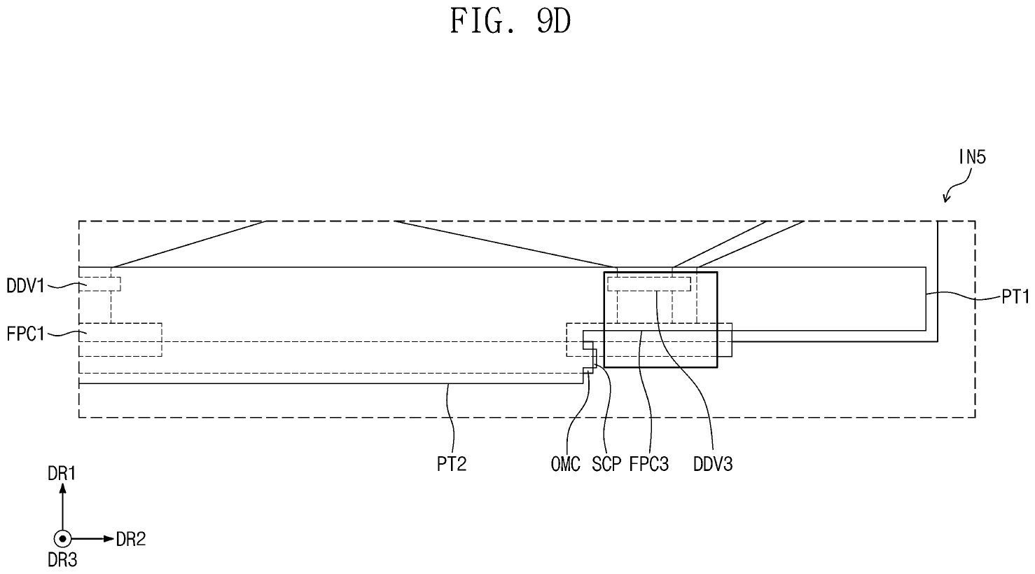

FIGS. 9A to 9D are views for describing a first cover according to an embodiment of the present disclosure.

FIGS. 9A to 9C are plan views.

FIG. 9B is an enlarged plan view of a fourth enlarged area IN4 illustrated in FIG. 9A, and FIG. 9D is an enlarged plan view of a fifth enlarged area IN5 illustrated in FIG. 9C.

FIGS. 9C and 9D are views illustrating a first cover CVP1a and the second cover CVP2 in a bent state.

The display module DM, the flexible circuit boards FPC, the main circuit board MCB, and the second cover CVP2 of FIGS. 9A and 9B are the same as the display module DM, the flexible circuit boards FPC, the main circuit board MCB, and the second cover CVP2 of FIGS. 6A and 7A, and thus a description thereof will be omitted or simplified.

Referring to FIGS. 9A and 9B, the first cover CVP1a may further include a plurality of sub-covers SCP. The sub-covers SCP may be arranged on both ends of the second part PT2, which are opposite to each other in the second direction DR2. The sub-covers SCP may be arranged adjacent to one side of each of the two sides of the second part PT2, which are opposite to each other in the first direction DR1. The one side of each of the two sides of the second part PT2, which are opposite to each other in the first direction DR1 may be defined as a side adjacent to the first part PT1.

The sub-covers SCP may extend in the second direction DR2 from both sides of the second part PT2, which are opposite to each other in the second direction DR2. Substantially, the second part PT2 and the sub-covers SCP may be integrally formed.

Referring to FIGS. 9C and 9D, the sub-covers SCP may be bent with respect to a bending axis parallel to the first direction DR1. The sub-covers SCP may be bent and cover a portion of the exposure board OMC exposed to the outside of the display panel DP. The sub-cover SCP may cover both sides of the exposure board OMC, which are opposite to each other in the second direction DR2. Accordingly, an area of the main circuit board MCB exposed to the outside may be reduced. Thus, damage to the main circuit board MCB from the external static electricity may be prevented and the noise generated in the vicinity of the main circuit board MCB may be prevented.

According to an embodiment of the present disclosure, first and second cover CVP1 and CVP2 may prevent static electricity from being generated on a flexible circuit board FPC and a main circuit board MCB and may block noise. The first cover CVP1 covers the flexible circuit board FPC and the main circuit board MCB, the second cover CVP2 covers a portion that is not covered by the first cover CVP1, and thus areas of the flexible circuit boards FPC and the main circuit board MCB exposed to the outside may be reduced. Accordingly, a possibility that static electricity is generated on the flexible circuit boards FPC and the main circuit board MCB may be reduced, and noise generated in the flexible circuit boards FPC and the main circuit board MCB may be blocked.

Although an embodiment has been described above, those skilled in the art may understand that the present disclosure may be variously modified and changed without departing from the spirit and scope of the present disclosure described in the appended claims. Further, it should be interpreted that an embodiment disclosed in the present disclosure is not intended to limit the technical spirit of the present disclosure and all technical spirits within the appended claims and equivalents thereto are included in the scope of the present disclosure.

What is claimed is:

1. A display device comprising:
a display panel;
a plurality of flexible circuit boards connected to the display panel and bent and disposed under the display panel;
a main circuit board connected to the flexible circuit boards and disposed under the display panel;
a first cover disposed on the display panel,
wherein the first cover is bent with a curvature and disposed on a rear surface of the display panel, covering portions of the flexible circuit boards and the main circuit board; and
a second cover covering parts of the flexible circuit boards which exposed from the first cover.

2. The display device of claim 1, wherein the second cover is bent with a curvature,
wherein the curvature of the first cover and the curvature of the second cover are different from each other.

3. The display device of claim 1, wherein the flexible circuit boards include:
a first flexible circuit board overlapping a center of an edge of the display panel in a plan view; and
a second flexible circuit board spaced apart from the first flexible circuit board in a second direction intersecting the first direction.

4. The display device of claim 3, wherein the first cover covers the first flexible circuit board and the main circuit board,
wherein the second cover covers the second flexible circuit board.

5. The display device of claim 1, wherein the main circuit board includes:
a first board connected to the flexible circuit board; and
a second board extending from the first board in the first direction.

6. The display device of claim 5, wherein a length of the first board in a second direction intersecting the first direction is longer than a length of the second board in the second direction.

7. The display device of claim 5, wherein the first cover includes:
a first part covering the flexible circuit boards;
a second part extending from the first part in the first direction and covering the second board; and
a third part extending from the second part in the first direction covering the first board.

8. The display device of claim 7, wherein, in a plan view, a length of the third part in a second direction intersecting the first direction is longer than a length of the second part in the second direction, and the length of the third part in the second direction is shorter than a length of the first part in the second direction.

9. The display device of claim 7, wherein the second cover is disposed on the first part and covers the second flexible circuit board.

10. The display device of claim 9, wherein, in a plan view, the second cover is disposed between the first part and the third part.

11. The display device of claim 7, wherein the first cover includes sub-covers arranged on both sides of the second part, which are opposite to each other in the second direction,
wherein the sub-covers cover portions of the second boards, which are opposite to each other in the second direction.

12. The display device of claim 1, wherein each of the first cover and the second cover includes:
a first cover insulating layer;
an intermediate layer disposed on the first cover insulating layer and including at least a metal or a conductive fiber; and
a second cover insulating layer disposed on the intermediate layer.

13. The display device of claim 12, wherein the intermediate layer is grounded to the main circuit board and the display panel.

14. The display device of claim 1, further comprising:
a data driver disposed on the display panel,
wherein the first cover covers the data driver.

15. A display device comprising:
a display panel;
a first flexible circuit board connected to and bent from a center of an edge of the display panel;
a second flexible circuit board connected to and bent from the edge of the display panel, spaced apart from the first flexible circuit board, and adjacent to one side of the edge of the display panel;
a main circuit board disposed on a lower surface of the display panel and connected to the first flexible circuit board and the second flexible circuit board;
a first cover covering the first flexible circuit board and the main circuit board; and
a second cover covering the second flexible circuit board.

16. The display device of claim 15, wherein the first cover includes:
a first part covering the first flexible circuit board;
a second part extending from the first part in a first direction and covering the main circuit board; and
a third part extending from the second part in the first direction and covering the main circuit board.

17. The display device of claim 16, wherein, in a plan view, a length of the third part in a second direction intersecting the first direction is longer than a length of the second part in the second direction, and the length of the third part in the second direction is shorter than a length of the first part in the second direction.

18. The display device of claim 16, wherein the first cover includes sub-covers disposed on both sides of the second part, which are opposite to each other in a second direction intersecting the first direction,
wherein the sub-covers cover portions of both sides of the main circuit boards, which are opposite to each other in the second direction.

19. The display device of claim 16, wherein, in a plan view, the second cover is disposed between the first part and the third part.

20. The display device of claim 15, wherein each of the first cover and the second cover includes:
a first cover insulating layer;
an intermediate layer disposed on the first cover insulating layer and including at least a metal or a conducive fiber; and
a second cover insulating layer disposed in the intermediate layer.
